(19) United States
(12) Patent Application Publication
(10) Pub. No.: US 2018/0113613 A1
(43) Pub. Date: Apr. 26, 2018

(54) INFORMATION RECEIVING DEVICE AND SEMICONDUCTOR DEVICE INCLUDING THE SAME

(71) Applicant: SK hynix Inc., Icheon-si Gyeonggi-do (KR)

(72) Inventor: Na Yeon KIM, Seoul (KR)

(73) Assignee: SK hynix Inc., Icheon-si Gyeonggi-do (KR)

(21) Appl. No.: 15/584,791

(22) Filed: May 2, 2017

(30) Foreign Application Priority Data
Oct. 24, 2016 (KR) 1020160138713

(51) Int. Cl. G06F 3/06; H03K 19/003; G11C 7/10; G11C 8/18

(52) U.S. Cl. CPC G06F 3/061; H03K 19/00384; G11C 8/18; G11C 7/109; G06F 3/0668; G06F 3/0659

(57) ABSTRACT

An information receiving device may include a comparator configured to compare a chip select signal and a preset chip ID signal, and a buffer enable signal generator configured to generate a buffer enable signal for enabling a buffer to receive information, based on the comparison result of the comparator.

### CROSS-REFERENCES TO RELATED APPLICATION

The present application claims priority under 35 U.S.C. § 119(a) to Korean application number 10-2016-0138713, filed on Oct. 24, 2016, in the Korean Intellectual Property Office, which is incorporated herein by reference in its entirety as though fully set forth herein.

### BACKGROUND

The present invention relates generally to an information receiving device and a semiconductor device including the same, and, more particularly, to a technique for transmitting information to a plurality of chips through a small number of lines in a semiconductor device including the plurality of chips.

Recently, more and more devices in various fields use a large amount of information in order to process images or big data. Thus, in order to process a large amount of information, it is important to increase the capacity of memory devices.

Therefore, a technique has been developed for mounting a plurality of chips in a module and storing information in each of the chips. In this case, however, the plurality of chips must be individually controlled. Thus, the number of lines applied to the respective chips inevitably increases.

### SUMMARY

Various embodiments are directed to a technique for transmitting information to a plurality of chips through a small number of lines in a semiconductor device including the plurality of chips.

In an embodiment in accordance with the present invention, an information receiving device includes: a comparator configured to compare a chip select signal and a preset chip ID signal; and a buffer enable signal generator configured to generate a buffer enable signal for enabling a buffer to receive information, based on the comparison result of the comparator.

In another embodiment in accordance with the present invention, a semiconductor device includes: a first information receiving device including: a first comparator configured to compare a chip select signal and a preset first chip ID signal; and a first buffer enable signal generator configured to generate a first buffer enable signal for enabling a first buffer to receive information, based on the comparison result of the first comparator, and a second information receiving device including: a second comparator configured to compare the chip select signal and a preset second chip ID signal; and a second buffer enable signal generator configured to generate a second buffer enable signal for enabling a second buffer to receive the information, based on the comparison result of the second comparator.

### BRIEF DESCRIPTION OF THE DRAWINGS

The above and other features and advantages of the present invention will become readily apparent by reference to the following detailed description when considered in conjunction with the accompanying drawings wherein:

FIG. 1 is a configuration diagram of a semiconductor device in an embodiment in accordance with the present invention;

FIG. 2 is a configuration diagram of an information receiving device of FIG. 1;

FIG. 3 is a table showing chip ID signals of chips included in the semiconductor device of FIG. 1;

FIG. 4 is a diagram schematically illustrating the hardware implementation of the chips of FIG. 1;

FIG. 5 is a circuit diagram of a comparator and a comparison result signal generator of FIG. 2;

FIG. 6 is a timing diagram illustrating signals of the information receiving device of FIG. 2;

FIG. 7 is a diagram schematically illustrating the hardware implementation of the semiconductor device of FIG. 1;

FIG. 8A is a diagram illustrating the numbers of pins and lines for chip select signals according to a comparative example;

FIG. 8B is a diagram illustrating the numbers of pins and lines for chip select signals in an embodiment in accordance with the present invention; and

FIG. 9 is a configuration diagram of a semiconductor system including a semiconductor device in an embodiment in accordance with the present invention.

### DETAILED DESCRIPTION

Hereinafter, embodiments in accordance with the present invention will be explained in more detail with reference to the accompanying drawings. Although the present invention is described with reference to a number of example embodiments thereof, it should be understood that numerous other modifications and variations may be devised by one skilled in the art that will fall within the spirit and scope of the invention.

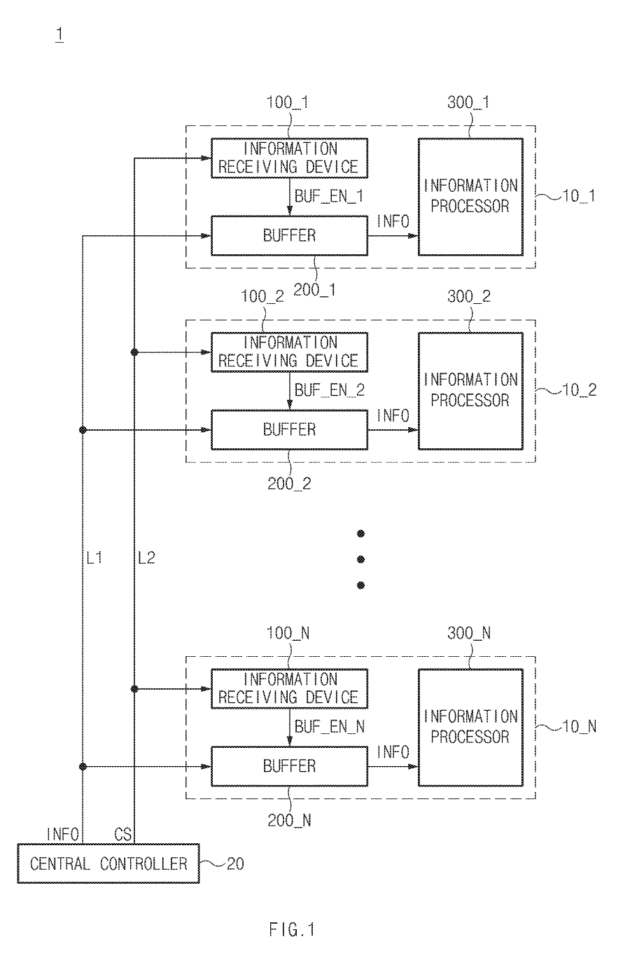

Referring to FIG. 1, the semiconductor device 1 includes a plurality of chips 10_1 to 10_N and a central controller 20. The plurality of chips 10_1 to 10_N may be represented by 10. For example, the chips 10_1 to 10_N may include memory chips such as DRAM and Flash memory, the central controller 20 may include a memory controller, and the semiconductor device 1 may include a memory module.

The chips 10_1 to 10_N include information receiving devices 100_1 to 100_N, buffers 200_1 to 200_N corresponding to the respective information receiving devices 100_1 to 100_N, and information processors 300_1 to 300_N corresponding to the respective buffers 200_1 to 200_N. The information receiving devices 100_1 to 100_N may be represented by 100, and the buffers 200_1 to 200_N may be represented by 200.

The central controller 20 relays data between the chips 10_1 to 10_N and an external device (not illustrated) of the semiconductor device 1. The external device of the semiconductor device 1 may include a CPU (Central Processing Unit), AP (Application Processor) or GPU (Graphic Processing Unit). The central controller 20 may transmit chip select signals CS and information INFO to the chips 10_1 to 10_N based on a command of the external device.

Between the central controller 20 and the buffers 200_1 to 200_N, a line L1 is connected in order to exchange the information INFO therebetween. Since the buffers 200_1 to 200_N are commonly coupled to the central controller 20 through the line L1, the information INFO is transmitted to the buffer 200_1 to 200_N in common.

The information INFO transmitted through the line L1 may include an address signal, RAS (Row Address Strobe) signal, CAS (Column Address Strobe) signal and WE (Write Enable) signal, for example.

Between the central controller 20 and the information receiving devices 100_1 to 100_N, a line L2 is connected in order to exchange a chip select signal CS therebetween. Since the information receiving devices 100_1 to 100_N are commonly connected to the central controller 20 through the line L2, the chip select signal CS is inputted to the information receiving devices 100_1 to 100_N in common.

The chip select signal CS has a plurality of bits. Thus, the line L2 may include a plurality of lines for transmitting the respective bits of the chip select signal CS.

The information receiving devices 100_1 to 100_N compare the chip select signal CS received from the central controller 20 to chip ID signals preset for the respective chips 10_1 to 10_N. Based on the comparison results, the information receiving devices 100_1 to 100_N generate buffer enable signals BUF_EN_1 to BUF_EN_N, respectively.

The buffers 200_1 to 200_N receive information INFO in response to the corresponding buffer enable signals BUF_EN_1 to BUF_EN_N.

The information processors 300_1 to 300_N process the respective pieces of information INFO received from the buffers 200_1 to 200_N.

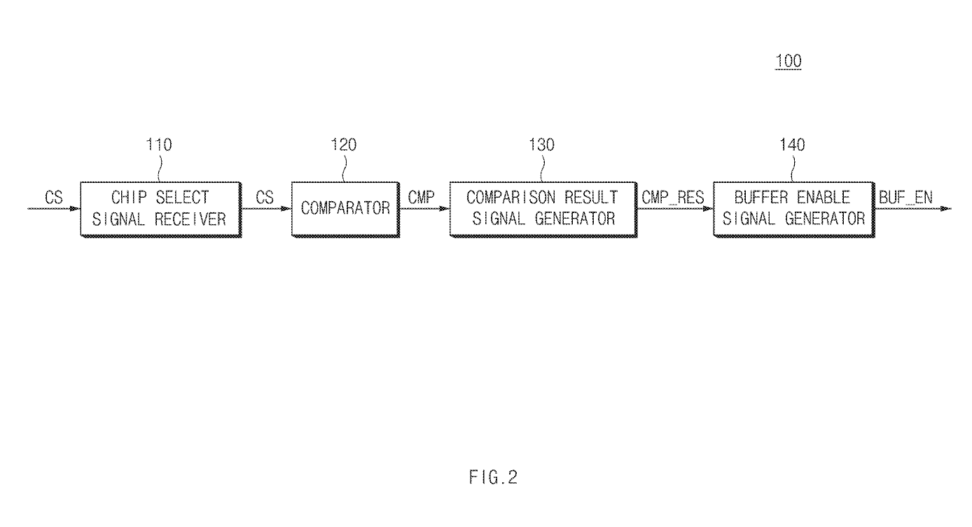

FIG. 2 is a configuration diagram of the information receiving device 100 of FIG. 1. The information receiving device 100 of FIG. 2 is included in each of the chips 10_1 to 10_N of FIG. 1.

Referring to FIG. 2, the information receiving device 100 includes a chip select signal receiver 110, a comparator 120, a comparison result signal generator 130 and a buffer enable signal generator 140.

The chip select signal receiver 110 receives the chip select signal CS having a plurality of bits, and transmits the received signal to the comparator 120. The chip select signal receiver 110 may include a buffer. The chip select signal CS having a plurality of bits is transmitted through the line L2 from the central controller 20 of FIG. 1.

The comparator 120 compares the chip select signal CS transmitted from the chip select signal receiver 110 to a chip ID signal CID, and generates a comparison signal CMP.

The chip ID signal CID may include a preset signal stored in each of the chips 10_1 to 10_N. The chip ID signal CID may be differently set for each of the chips 10_1 to 10_N. The chip ID signal CID contains a plurality of bits, and has the same number of bits as the chip select signal CS.

The chip ID signal CID may be set by applying a high-level or low-level voltage to each of a plurality of pads installed in the respective chips 10_1 to 10_N. The low-level voltage may include a ground voltage. The applied voltage may include voltages applied from outside the chips 10_1 to 10_N or internal voltages which are generated by the chips_1 to 10_N using an external voltage.

The comparator 120 compares the chip ID signal CID preset for each of the chips 10_1 to 10_N to the chip select signal CS, and generates the comparison signal CMP. For example, the comparator 120 may compare the bits of the chip ID signal CID to the respective bits of the chip select signal CS, and generate the comparison signal CMP corresponding to the respective bits of the chip ID signal CID and the chip select signal CS.

The comparison result signal generator 130 generates a comparison result signal CMP_RES based on the comparison signal CMP. For example, the comparison result signal CMP_RES may be enabled when the bits of the comparison signal CMP are all enabled. That is, the comparison result signal CMP_RES may be enabled when the chip ID signal CID and the chip select signal CS coincide with each other, or disabled when the chip ID signal CID and the chip select signal CS do not coincide with each other.

When the chip ID signal CID of any one chip coincides with the chip select signal CS in a case where the chip ID signal CID is differently set for each of the chips 10_1 to 10_N, the chip ID signals CID of the other chips do not coincide with the chip select signal CS. Thus, the comparison result signal CMP_RES may be enabled for any one chip, and disabled for the other chips.

The buffer enable signal generator 140 generates the buffer enable signal BUF_EN based on the comparison result signal CMP_RES. Thus, referring to FIG. 1, the buffers 200_1 to 200_N in which the buffer enable signal BUF_EN is enabled can receive the information INFO, and the information receiving devices 300_1 to 300_N can use the information INFO.

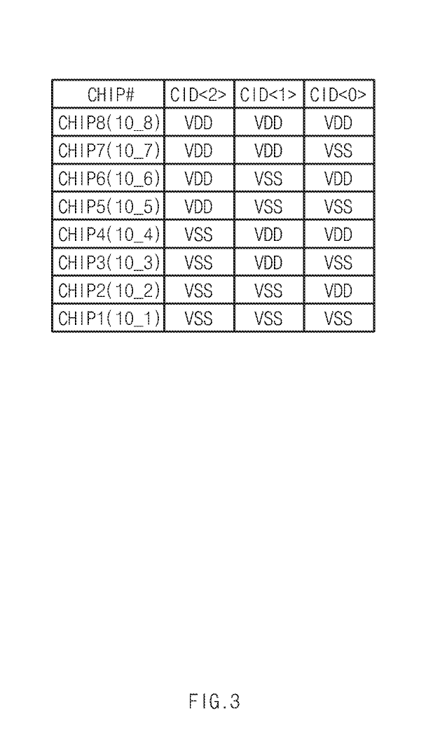

FIG. 3 is a table showing the chip ID signals CID of the respective chips 10_1 to 10_N of FIG. 1. FIG. 3 is based on the supposition that the number of chips 10_1 to 10_N included in the semiconductor device 1 of FIG. 1 is set to eight and the chip ID signal has three bits.

Referring to FIG. 3, the chip 10_1 is configured to have a chip ID signal CID of “000”. For this configuration, the low-level voltage VSS is applied to the respective bits CID<2> to CID<0> of the chip ID signal of the chip 10_1.

The chip 10_2 is configured to have a chip ID signal CID of “001”. For this configuration, the high-level voltage VDD is applied to the zeroth bit of the chip ID signal CID, and the low-level voltage VSS is applied to the first and second bits of the chip ID signal CID.

In this way, the chip ID signals CID of the chips 10_3 to 10_8 are set to “010”, “011”, “100”, “101”, “110” and “111”, respectively.

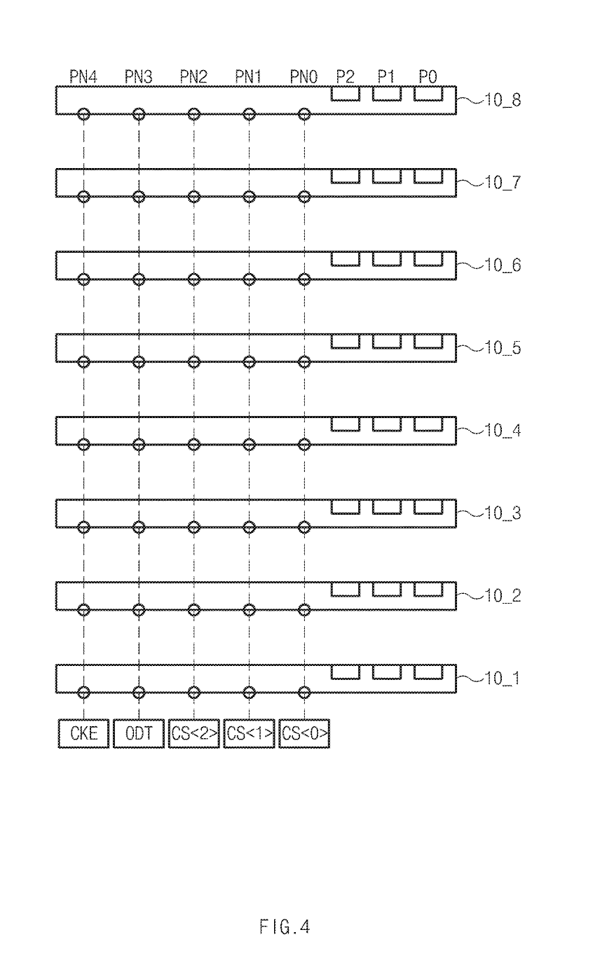

FIG. 4 is a diagram schematically illustrating the hardware implementation of the chips 10_1 to 10_N of FIG. 1. FIG. 4 is also based on the supposition that the number of chips 10_1 to 10_N included in the semiconductor device is set to eight and the chip ID signal has three bits.

Referring to FIG. 4, each of the chips 10_1 to 10_8 includes three pads P0 to P2. A low-level or high-level voltage may be applied to the pads in order to set the chip IDs of the respective chips 10_1 to 10_8.

For example, voltage levels corresponding to the chip ID signals CID<0> to CID<2> of FIG. 3 may be set to the pads P0 to P2. That is, the low-level voltage may be applied to the pads P0 to P2 of the chip 10_1, the high-level voltage may be applied to the pad P0 to the chip 10_2, and the low-level voltage may be applied to the pads P1 and P2 of the chip 10_2. In this way, the high-level voltage is applied to the pads P0 and P1 of the chip 10_8.

Each of the chips 10_1 to 10_8 includes a plurality of pins PN0 to PN4 to receive chip select signals CS<0> to CS<2>, a clock enable signal CKE and an on-die termination signal ODT. The clock enable signal CKE and the on-die termination signal ODT are examples of the information INFO of FIG. 1. The chip select signals CS<0> to CS<2>, the clock enable signal CKE and the on-die termination signal ODT are transmitted from the central controller 20 of FIG. 1.

As indicated by the dashed lines in FIG. 4, pins set to the same number in the respective chips 10_1 to 10_8 are connected to a common line. That is, the pins PN0, to receive the chip select signal CS<0> of the zeroth bit, may be connected to a common line, and the pins PN1, to receive the chip select signal CS<1> of the first bit, may be connected to a common line.

Three lines which are connected to the pins PN0 to PN2 to transmit the chip select signals CS<0> to CS<2>, respectively, correspond to the line L2 of FIG. 1. Two lines which are connected to the pins PN3 and PN4 to transmit the clock enable signal CKE and the on-die termination signal ODT correspond to the line L1 of FIG. 1.

The chip ID signals CID<0> to CID<2> for the respective chips 10_1 to 10_8 are set through the pads P0 to P2 as indicated in FIG. 3. The information receiving devices 100_1 to 100_8 included in the respective chips 10_1 to 10_8 compare the chip ID signals CID<0> to CID<2> to the chip select signals CS<0> to CS<2> applied to the pins PN0 to PN2. When the chip ID signals CID<0> to CID<2> coincide with the chip select signals CS<0> to CS<2>, the information receiving devices 100_1 to 100_8 enable the buffer enable signal BUF_EN to receive the clock enable signal CKE and the on-die termination signal ODT.

For example, when “011” is inputted as the chip select signal CS, the value coincides with “011” which is the value of the chip ID signal CID of the chip 10_4. Thus, the information receiving device 100_3 included in the chip 10_3 enables the buffer enable signal BUF_EN_3 which controls the buffer 200_3 of the chip 10_3 to store the clock enable signal CKE and the on-die termination signal ODT. The chip select signal CS of “011” does not coincide with the chip ID signals CID of the other chips 10_1, 10_2 and 10_4 to 10_8. Thus, the information receiving devices 100_1, 100_2 and 100_4 to 100_8 included in the chips 10_1, 10_2 and 10_4 to 10_8 disable the buffer enable signals BUF_EN_1, BUF_EN_2 and BUF_EN_4 to BUF_EN_8 such that the buffers 200_1, 200_2 and 200_4 to 200_8 included in the chips 10_1, 10_2 and 10_4 to 10_8 do not store the clock enable signal CKE and the on-die termination signal ODT.

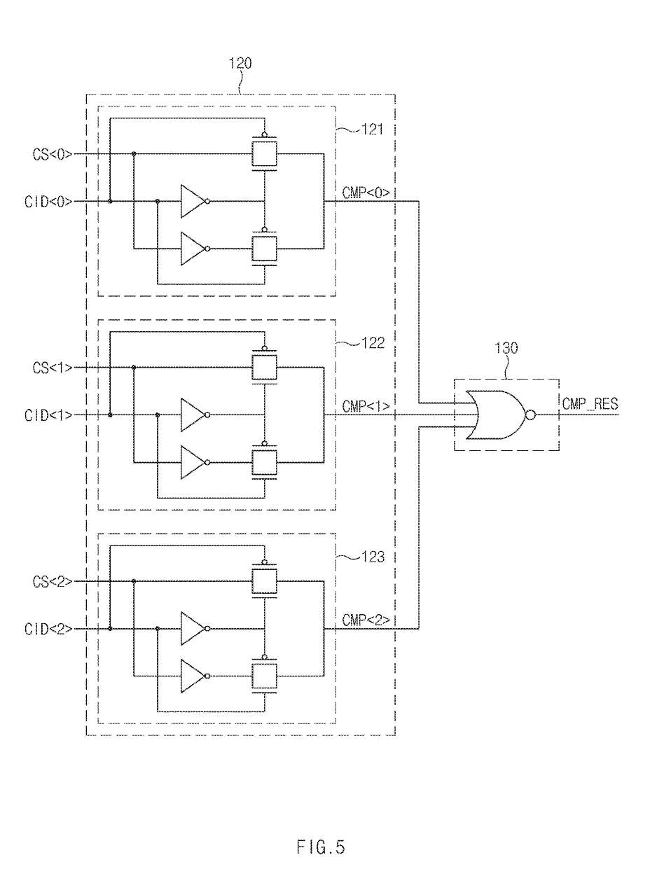

FIG. 5 is a detailed circuit diagram of the comparator 120 and the comparison result signal generator 130 of FIG. 2. The comparator 120 compares the bits of the chip select signal CS to the respective bits of the chip ID signal CID, and generates the comparison signal CMP having the same number of bits as the chip select signal CS or the chip ID signal CID. The comparator 120 includes bit comparison circuits 121 to 123 for comparing the bits CS<2> to CS<0> of the chip select signal to the respective bits CID<2> to CID<0> of the chip ID signal.

The bit comparison circuit 121 compares the chip select signal CS<0> of the zeroth bit to the chip ID signal CID<0> of the zeroth bit, and enables the comparison signal CMP<0> of the zeroth bit when the chip select signal CS<0> coincides the chip ID signal CID<0>. The bit comparison circuit 122 compares the chip select signal CS<1> of the first bit to the chip ID signal CID<1> of the first bit, and enables the comparison signal CMP<1> of the first bit when the chip select signal CS<1> coincides the chip ID signal CID<1>. The bit comparison circuit 123 compares the chip select signal CS<2> of the second bit to the chip ID signal CID<2> of the second bit, and enables the comparison signal CMP<2> of the second bit when the chip select signal CS<2> coincides the chip ID signal CID<2>. Thus, the comparison signals CMP<2> to CMP<0> are generated by the comparator 120.

The comparison result signal generator 130 generates the comparison result signal CMP_RES based on the comparison signal CMP. Specifically, when the bits CMP<2> to CMP<0> of the comparison signal are all enabled, the comparison result signal generator 130 enables the comparison result signal CMP_RES. When the bits CMP<2> to CMP<0> of the comparison signal are enabled to a high level, the comparison result signal generator 130 may perform an AND operation on the bits CMP<2> to CMP<0> of the comparison signal, and output the comparison result signal CMP_RES. On the other hand, when the bits CMP<2> to CMP<0> of the comparison signal are enabled to a low level, the comparison result signal generator 130 may perform a NOR operation on the bits CMP<2> to CMP<0> of the comparison signal, and output the comparison result signal CMP_RES. The buffer enable signal generator 140 generates the buffer enable signal BUF_EN based on the comparison result signal CMP_RES.

Specifically, when the comparison result signal CMP_RES is enabled, the buffer enable signal generator 140 enables the buffer enable signal BUF_EN. The buffer enable signal generator 140 may be implemented with a shift register. For example, the comparison result signal CMP_RES may be inputted in the form of pulses, and the buffer enable signal generator 140 may generate the buffer enable signal BUF_EN by adjusting the period in which the comparison result signal CMP_RES is enabled. The period in which the comparison result signal CMP_RES is enabled may be adjusted according to the characteristics of the buffers 200_1 to 200_N.

Thus, as illustrated in FIG. 1, the buffers 200_1 to 200_N are enabled by the buffer enable signals BUF_EN_1 to BUF_EN_N and receive the information INFO. The received information INFO may be used by the corresponding information processors 300_1 to 300_N.

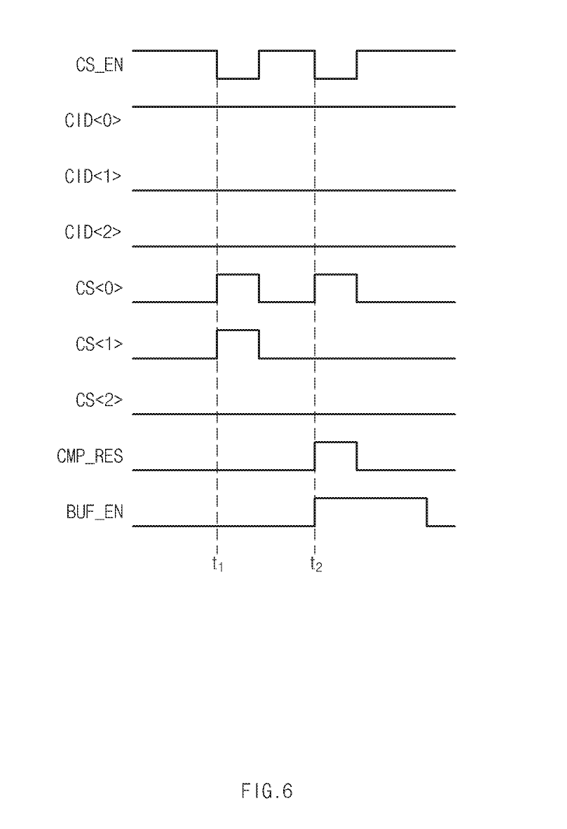

FIG. 6 is a timing diagram illustrating the signals of the information receiving device 100 of FIG. 2. FIG. 6 is based on the supposition that the chip ID signal CID for the information receiving device 100 is set to “001”.

Referring to FIG. 6, a chip select signal CS of “011” is inputted at t1. Since the chip select signal CS of “011” does not coincide with the chip ID signal CID of “001”, the comparison result signal CMP_RES is disabled to a low level. Therefore, the buffer enable signal BUF_EN is also disabled to a low level.

At t2, a chip select signal CS of “001” is inputted. Since the chip select signal CS of “001” coincides with the chip ID signal CID of “001”, the comparison result signal CMP_RES is enabled to a high level. Thus, the buffer enable signal BUF_EN is also enabled to a high level. At this time, the enable period of the buffer enable signal BUF_EN may be expanded more than that of the comparison result signal CMP_RES, such that the output operation of the buffer 200 can be performed in a stable manner.

In FIG. 6, the bits CS<2> to CS<0> of the chip select signal are inputted with the chip select enable signal CS_EN. In other words, only when the chip select enable signal CS_EN is enabled, the bits CS<2> to CS<0> of the chip select signal are processed as valid values. This is in order to prevent an unexpected input of the bits CS<2> to CS<0> of the chip select signal due to noise or the like.

The chip select enable signal CS_EN may be added to the chip select signal CS. Alternatively, in order to reduce the number of lines, a line for another signal which is applied to the plurality of chips 10_1 to 10_N in common may be used.

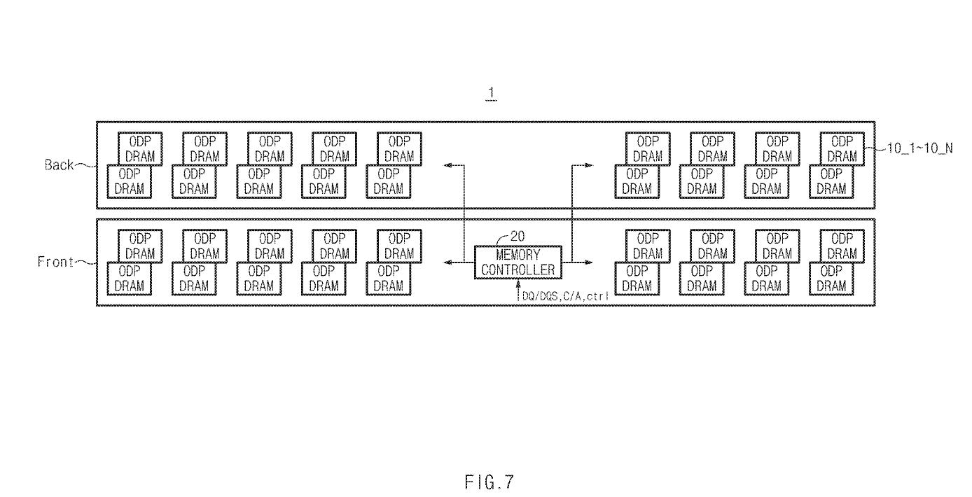

FIG. 7 is a diagram schematically illustrating the hardware implementation of the semiconductor device of FIG. 1. As illustrated in FIG. 7, the semiconductor device 1 may include a memory module, and the central controller 20 may include a memory controller.

The memory module 1 may include one memory controller 20 mounted therein. Furthermore, a plurality of ODP (Octa-Die Package) DRAMs may be mounted on the front and back surfaces of the memory module 1. The ODP DRAM may indicate a structure in which eight chips (for example, DRAMs) are stacked. For example, the chips 10_1 to 10_N of FIG. 1 may constitute the ODP DRAM.

As illustrated in FIG. 7, the high-density memory module 1 may include a large number of chips 10 mounted therein. Thus, the number of lines connected to the respective chips from the memory controller may be increased. In order to arrange a large number of chips and lines in the limited area of the memory module 1, the number of lines needs to be controlled such that the number of lines does not increase.

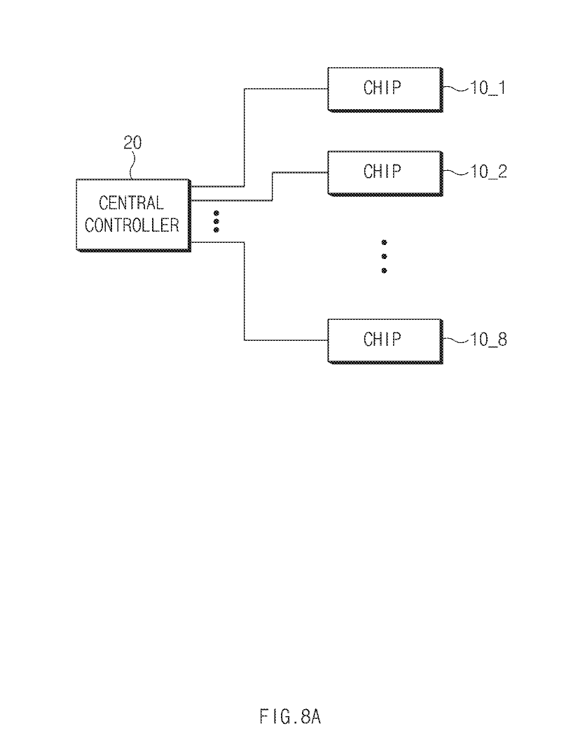

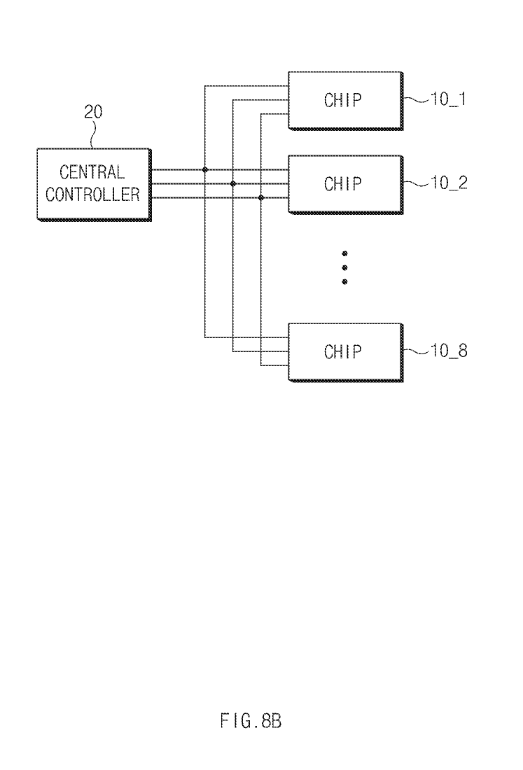

FIG. 8A is a diagram illustrating the numbers of pins and lines for chip select signals according to a comparative example. FIG. 8B is a diagram illustrating the numbers of pins and lines for chip select signals according to an example embodiment. FIGS. 8A and 8B are based on the supposition that eight chips 10 are used.

Referring to FIG. 8A, the central controller 20 may use eight lines to transmit chip select signals CS_1 to CS_8 to the respective chips 10_1 to 10_8. In this example, each of the chips 10_1 to 10_8 needs to have eight pins for receiving the chip select signals CS_1 to CS_8.

On the contrary, referring to FIG. 8B, the central controller 20 may use three lines to transmit the chip select signals CS<0> to CS<2> to the chips 10_1 to 10_8. Each of the chips 10_1 to 10_8 has three pins to receive the chip select signals CS<0> to CS<2>. In an embodiment in accordance with the present invention, the numbers of lines and pins can be reduced.

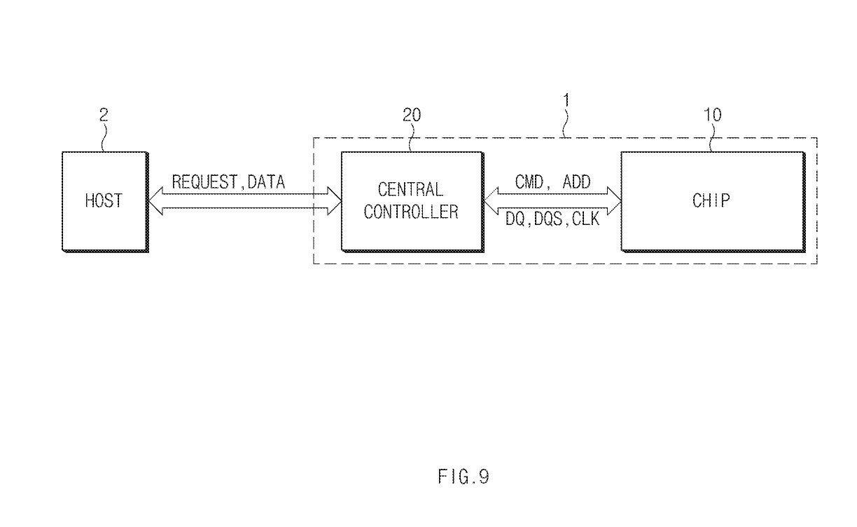

As illustrated in FIG. 9, the semiconductor system may include a host 2 and a semiconductor device (memory module) 1, and the semiconductor device 1 may include a central controller (memory controller) 20 and a chip 10. The chip 10 of FIG. 9 may represent the plurality of chips 10_1 to 10_N illustrated in FIG. 1. Although not illustrated in FIG. 9, the chip 10 may include an information receiving device 100, a buffer 200 and an information processor 300, as in FIG. 1.

The host 2 may transmit a request and data to the central controller 20 in order to access the chip 10. The host 2 may transmit data to the central controller 20 in order to store the data in the chip 10. Furthermore, the host 2 may receive data outputted from the chip 10 through the central controller 20. The central controller 20 may provide data information, address information, memory setting information, a write request, a read request or the like to the chip 10 in response to a request, and control the chip 10 to perform a write or read operation. The central controller 20 may relay communication between the host 2 and the chip 10. The central controller 20 may receive a request and data from the host 2, generate DATA DQ, a data strobe signal DQS, a command CMD, a memory address ADD, a clock signal CLK or the like, and provide the generated data or signal to the chip 10, in order to control the chip 10. The central controller 20 may provide the data DQ and data strobe signal DQS from the chip 10 to the host 2. The chip 10 may include the above-described information receiving device 100.

Thus, when the command CMD and address ADD are inputted from the central controller 20, the information receiving device 100 may compare a chip select signal CS contained in the command CMD to a chip ID signal CID. When the chip select signal CS coincides with the chip ID signal CID, the information receiving device 100 stores one or more of the command CMD, the address ADD, the data DQ, the data strobe signal DQS and the clock signal CLK, which are transmitted from the central controller 20, in the buffer 200.

FIG. 9 illustrates that the host 2 and the central controller 20 are physically separated from each other. However, the central controller 20 may be included (mounted) in processors such as CPU, AP and GPU of the host 2, or implemented as one chip with the processors in the form of SoC (System on Chip).

The information processor 300 of FIG. 10 performs a predetermined operation using the command CMD, the address ADD, the data DQ, the data strobe signal DQS and the clock signal CLK, which are received from the central controller 20.

The chip 10 may include a plurality of memory banks, and store the data DQ in a specific bank among the plurality of memory banks, based on the address ADD. Furthermore, the chip 10 may perform a data transmission operation based on the command CMD, the address ADD and the data strobe signal DQS which are received from the central controller 20. The chip 10 may transmit data stored in a specific bank among the memory banks to the central controller 20, based on the address ADD, the data DQ and the data strobe signal DQS.

In an embodiment in accordance with the present invention, the information receiving device may receive information by comparing a chip select signal to a preset chip ID signal. The number of bits contained in the chip select signal and the chip ID signal may be set to a smaller value than the number of chips. Therefore, the number of lines for the chip select signal can be reduced.

While certain embodiments have been described above, it will be understood by those skilled in the art that the embodiments described are by way of example only. Accordingly, the semiconductor device described herein should not be limited based on the described embodiments. Rather, the semiconductor device described herein should only be limited in light of the claims that follow when taken in conjunction with the above description and accompanying drawings.

What is claimed is:

1. An information receiving device comprising:
a comparator configured to compare a chip select signal and a preset chip ID signal; and
a buffer enable signal generator configured to generate a buffer enable signal for enabling a buffer to receive information, based on the comparison result of the comparator.

2. The information receiving device of claim 1, wherein the chip ID signal is set by applying a predetermined voltage to a pad mounted on a chip having the information receiving device.

3. The information receiving device of claim 1, wherein the chip select signal and the chip ID signal have an equal number of bits.

4. The information receiving device of claim 3, wherein the comparator compares the bits of the chip select signal to the respective bits of the chip ID signal.

5. The information receiving device of claim 1, further comprising a chip select signal receiver configured to receive the chip select signal.

6. The information receiving device of claim 1, wherein the information comprises one or more of an address signal, RAS (Row Address Strobe) signal, CAS (Column Address Strobe) signal and WE (Write Enable) signal.

7. A semiconductor device comprising:
a first information receiving device comprising: a first comparator configured to compare a chip select signal and a preset first chip ID signal; and a first buffer enable signal generator configured to generate a first buffer enable signal for enabling a first buffer to receive information, based on the comparison result of the first comparator, and
a second information receiving device comprising: a second comparator configured to compare the chip select signal and a preset second chip ID signal; and a second buffer enable signal generator configured to generate a second buffer enable signal for enabling a second buffer to receive the information, based on the comparison result of the second comparator.

8. The semiconductor device of claim 7, wherein the first and second chip ID signals are different from each other.

9. The semiconductor device of claim 8, wherein the first information receiving device is installed in a first chip, and
the second information receiving device is installed in a second chip.

10. The semiconductor device of claim 9, wherein the first chip ID signal is set by applying a first voltage to a first pad mounted on the first chip, and the second chip ID signal is set by applying a second voltage to a second pad mounted on the second chip.

11. The semiconductor device of claim 9, wherein the chip select signal, the first chip ID signal and the second chip ID signal have an equal number of bits.

12. The semiconductor device of claim 11, wherein the number of bits is smaller than the number of chips installed in the semiconductor device.

13. The semiconductor device of claim 11, wherein the first comparator compares the bits of the chip select signal to the respective bits of the first chip ID signal, and
the second comparator compares the bits of the chip select signal to the respective bits of the second chip ID signal.

14. The semiconductor device of claim 7, wherein the first information receiving device further comprises a first chip select signal receiver configured to receive the chip select signal, and
the second information receiving device further comprises a second chip select signal receiver configured to receive the chip select signal.

15. The semiconductor device of claim 7, wherein the information comprises one or more of an address signal, RAS signal, CAS signal and WE signal.

16. The semiconductor device of claim 7, further comprising a central controller configured to transmit the chip select signal and the information.
